(19) United States
(12) Patent Application Publication
(10) Pub. No.: US 2024/0247737 A1
(43) Pub. Date: Jul. 25, 2024

(54) CABLE MANAGEMENT BUNDLE CLIP

(71) Applicant: viaPhoton, Inc., Aurora, IL (US)

(72) Inventors: Keith Samuel MARANTO, Frankfort, IL (US); Mark James SMRHA, Chicago, IL (US)

(73) Assignee: viaPhoton, Inc., Aurora, IL (US)

(21) Appl. No.: 18/418,175

(22) Filed: Jan. 19, 2024

Related U.S. Application Data
(60) Provisional application No. 63/480,946, filed on Jan. 20, 2023.

(51) Int. Cl. F16L 3/223; F16L 3/13; H05K 7/14

(52) U.S. Cl. CPC F16L 3/2235; F16L 3/13; H05K 7/1491

(57) ABSTRACT

An apparatus implements a cable management bundle clip. The apparatus includes multiple cylindrical channels to secure multiple cables. The apparatus further includes a wall of a cylindrical channel that includes multiple curves. The apparatus further includes an edge of the wall between an interior surface and an exterior surface. The edge includes a convex curvature and a concave curvature. The convex curvature is proximal to a center of the bundle clip and the concave curvature distal to the center of the bundle clip.

### CROSS REFERENCE TO RELATED APPLICATIONS

This application claims the benefit of U.S. Provisional Application 63/480,946, filed Jan. 20, 2023, which is incorporated by reference herein.

### BACKGROUND

Cables, including fiber optic cables, may be terminated by modules. The modules and cables may be installed in the servers, racks, trays, panels, etc. at a data center to provide lines of communication between telecommunications equipment. During installation, the cables and modules may be pulled through various conduits and tight spaces and around corners. A problem with installation is that the cables may separate and get caught or snagged to frustrate installation.

### SUMMARY

In general, in one or more aspects, the disclosure relates to an apparatus implementing a cable management bundle clip. The apparatus includes multiple cylindrical channels to secure multiple cables. The apparatus further includes a wall of a cylindrical channel that includes multiple curves. The apparatus further includes an edge of the wall between an interior surface and an exterior surface. The edge includes a convex curvature and a concave curvature. The convex curvature is proximal to a center of the bundle clip and the concave curvature distal to the center of the bundle clip.

In general, in one or more aspects, the disclosure relates to a system implementing a cable management bundle clip. The system includes multiple bundle clips. A bundle clip of the multiple bundle clips includes multiple cylindrical channels to secure multiple cables. A bundle clip of the multiple bundle clips further includes a wall of a cylindrical channel. The wall includes multiple curves. A bundle clip of the multiple bundle clips further includes an edge of the wall between an interior surface and an exterior surface. The edge includes a convex curvature and a concave curvature, wherein the convex curvature is proximal to a center of the bundle clip and the concave curvature distal to the center of the bundle clip. The system further includes multiple cables disposed within the channels. The system further includes at least one module connected to the cables. The module includes multiple adapters corresponding to multiple cables and to multiple channels of the bundle clip.

A method installs cable using a cable management bundle clip. The method includes inserting cables into channels of one or more bundle clips. A bundle clip of the bundle clips includes multiple cylindrical channels to secure multiple cables. A bundle clip of the bundle clips further includes a wall of a cylindrical channel. The wall includes multiple of curves. A bundle clip of the bundle clips further includes an edge of the wall between an interior surface and an exterior surface. The edge includes a convex curvature and a concave curvature. The convex curvature is proximal to a center of the bundle clip and the concave curvature distal to the center of the bundle clip. The method further includes installing the cables to a set of telecommunications equipment.

Other aspects of one or more embodiments of the disclosure will be apparent from the following description and the appended claims.

### BRIEF DESCRIPTION OF DRAWINGS

FIG. 1 shows a block diagram in accordance with one or more embodiments of the disclosure.

FIG. 2 shows a method in accordance with one or more embodiments of the disclosure.

FIG. 3, FIG. 4, FIG. 5, FIG. 6, FIG. 7, and FIG. 8 show examples in accordance with one or more embodiments of the disclosure.

Similar elements in the various figures are denoted by similar names and reference numerals. The features, elements, methods, etc., described in one figure may extend to and be used by similarly named features, elements, methods, etc., in different figures.

### DETAILED DESCRIPTION

In general, one or more embodiments are directed to a cable management bundle clip. The bundle clip prevents cables from snagging and getting caught during installation by preventing the separation of cables. The bundle clip includes several features to secure cables and prevent snagging or getting stuck on obstructions when being pulled through pathways to be installed at a facility.

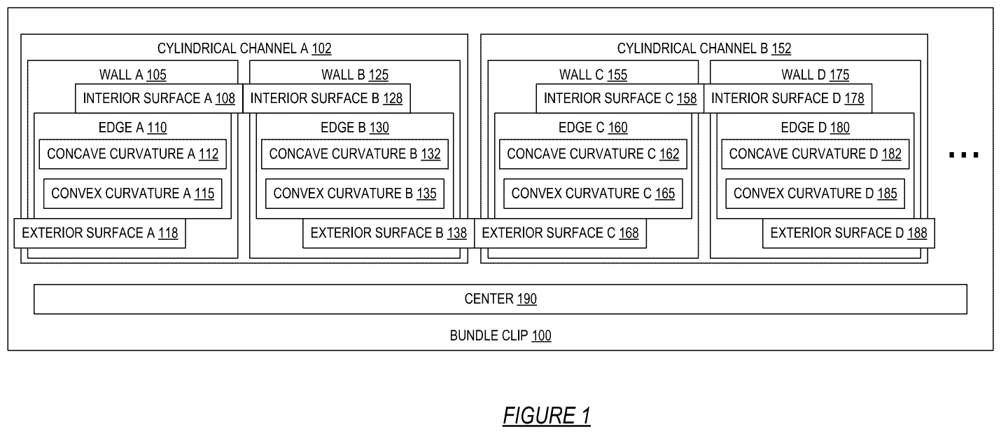

Turning to FIG. 1, a block diagram depicts the bundle clip (100). The bundle clip (100) may secure multiple cables (not shown) using the cylindrical channels A (102) and B (152). In an embodiment, the bundle clip (100) may include at least three cylindrical channels, including the cylindrical channels A (102) and B (152).

The cylindrical channel A (102) is a cavity in the bundle clip (100) structured to receive a cable. The cylindrical channel A (102) includes the walls A (105) and B (125). The wall A (105) includes the edge A (110) between the interior surface A (108) and the exterior surface A (118). The interior surface A (108) may contact a cable (not shown) when inserted into the cylindrical channel A (102).

The edge A (110) includes the concave curvature A (112) and the convex curvature A (115). The convex curvature A (115) is proximal to the center (190) of the bundle clip (100) and the concave curvature A (112) is distal to the center (190) of the bundle clip (100). The concave curvature A (112) and the convex curvature A (115) may combine to form an S shaped curve.

The wall B (125) is a second wall of the cylindrical channel A (102). The cylindrical channel B (152) includes the walls C (155) and D (175). The walls B (125), C (155), and D (175) include the interior surfaces B (128), C (158), and D (178), the edges B (130), C (160), and D (180), the concave curvatures B (132), C (162), and D (182), the convex curvatures B (135), C (165), and D (185), and the exterior surfaces B (138), C (168), and D (188), which have similar structures and operations as those from similarly named features of the wall A (105).

Each of the walls A (105), B (125), C (155), and D (175) include surfaces that connect between other walls. For example, the interior surface A (108) of the wall A (105) extends and connects to the interior surface B (128) of the wall B (125). The exterior surface B (138) of the wall B (125) of the cylindrical channel A (102) extends and connects to the exterior surface C (168) of the wall C (155) of the cylindrical channel B (152).

The center (190) is a central portion of the bundle clip (100) around which the cylindrical channels A (102) and B (152) may be positioned. The convex curvatures A (115), B (135), C (165), and D (185) are proximal to the center (190) and the concave curvatures A (112), B (132), C (162), and D (182) are distal to the center (190).

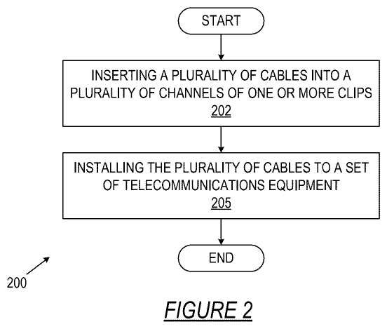

Turning to FIG. 2, the method (200) uses a bundle clip to install cabling in communication networks. The method (200) may be performed using the systems and components described in the other figures.

Step 202 includes inserting cables into the channels of one or more bundle clips. One of the bundle clips includes multiple cylindrical channels to secure a plurality of cables, multiple walls with multiple curves with convex and concave curvatures. The convex curvatures are proximal to a center of the bundle clip and the concave curvatures are distal to the center of the bundle clip. Inserting a cable into a cylindrical channel may include pressing the cable into an opening between the walls of the cylindrical channel. Multiple cables may be inserted into one bundle clip. Multiple bundle clips may be used along the lengths of multiple cables.

At Step 205, the method (200) includes installing the cables to a set of telecommunications equipment. The cables secured into the bundle clips may be pulled through conduits and tight spaces and around corners at a data center.

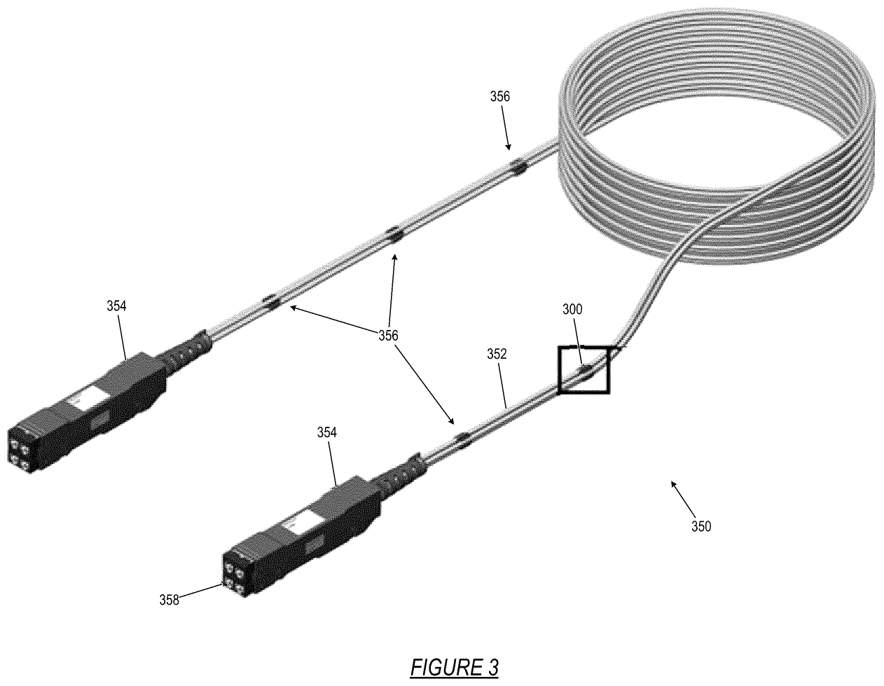

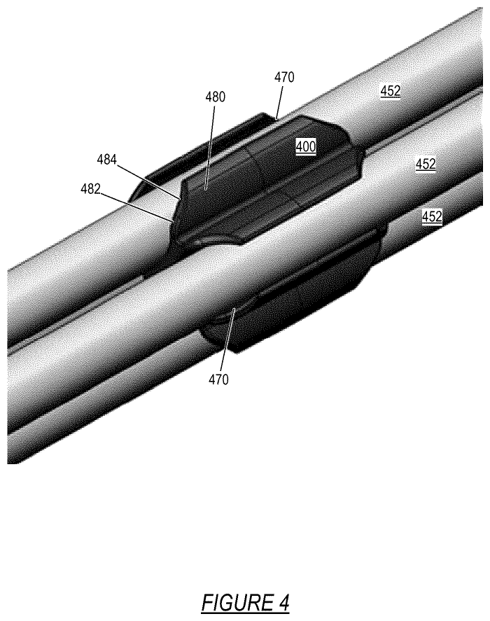

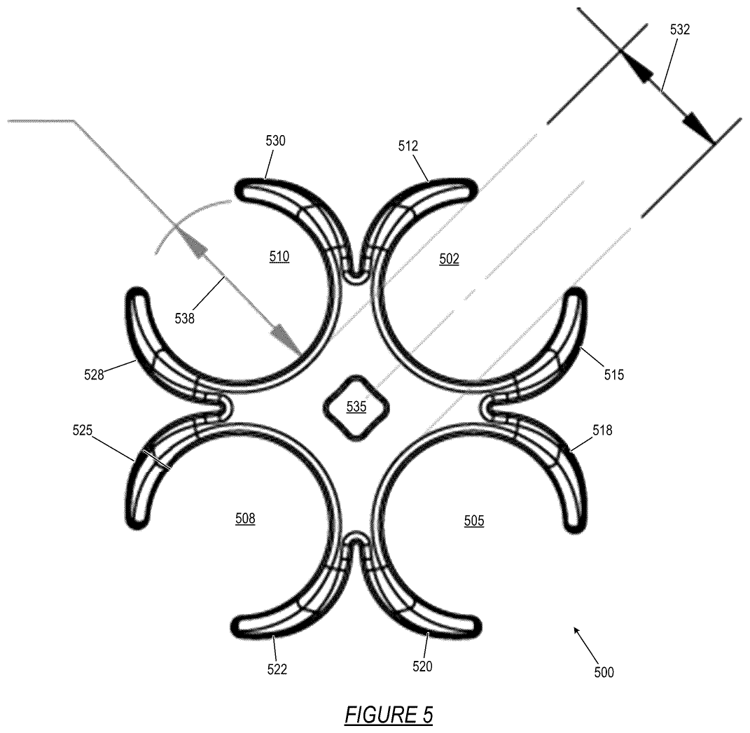

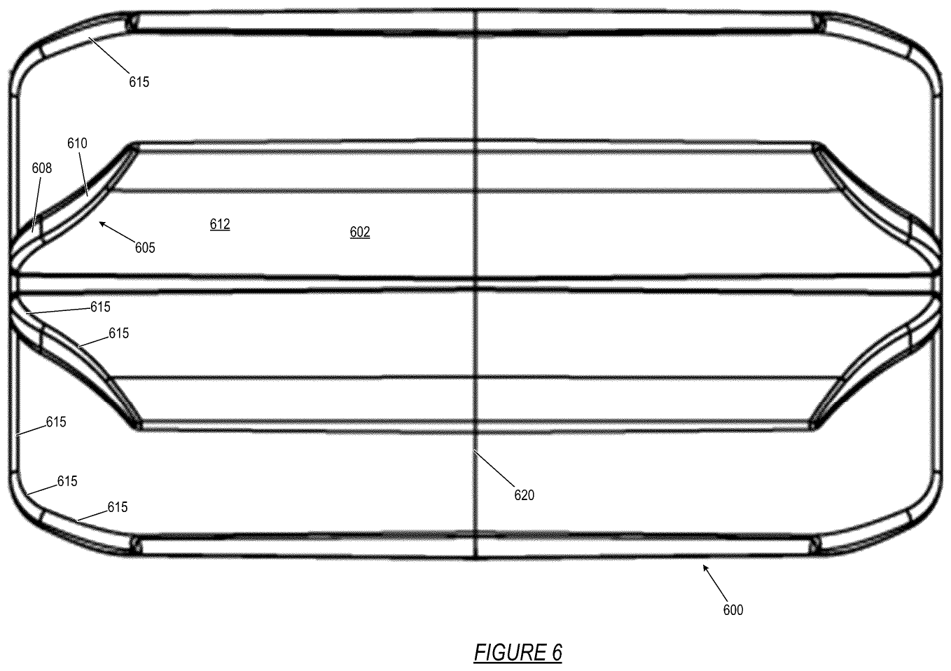

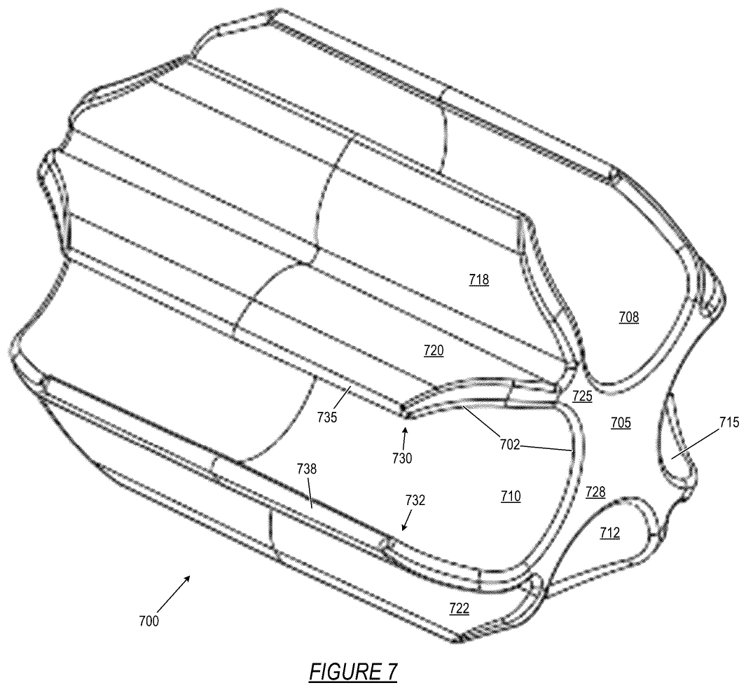

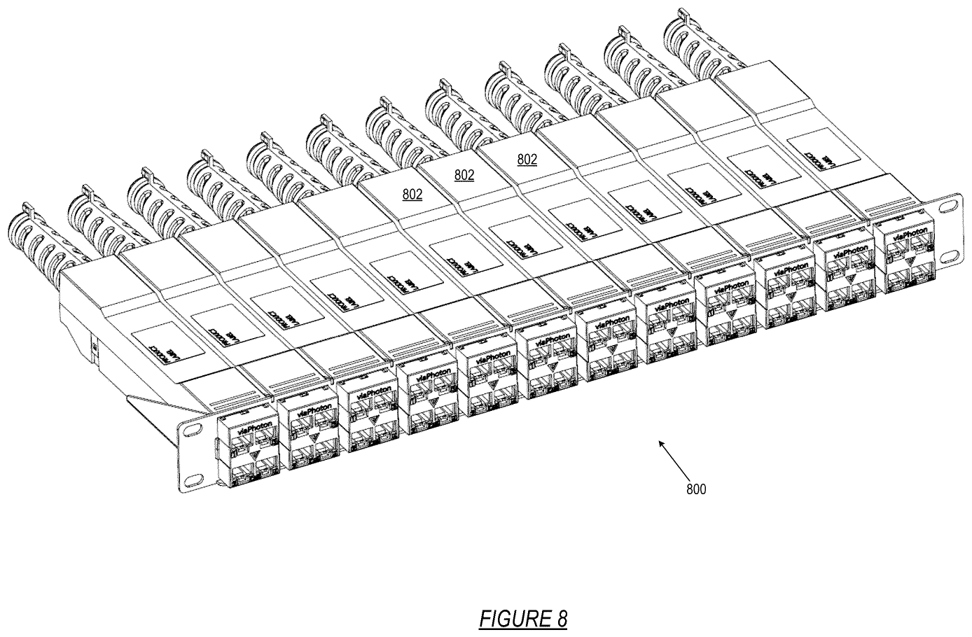

Turning to FIG. 3, the bundle clip (300) is used as part of the cable system (350). The cable system (350) includes the cables (352), the modules (354), and the bundle clips (356) (which include the bundle clip (300)).

The cables (352) connect between the modules (354). In one embodiment, the cables (352) are ethernet cables. In one embodiment, the cables (352) include a cable for each of the adapters (358) of the modules (354). Different endpoints (other than the modules (354)) may be used.

The modules (354) couple the cables (352) to the adapters (358). In one embodiment, each of the modules (354) includes four adapters, which correspond to four cables.

The bundle clips (356) include the bundle clip (300). The bundle clips (356) are structured to secure the cables (352) outside of the modules (354). The bundle clips (356) bundle and secure the cables (352) together so that the cables (352) may be installed by pulling one of the modules (354) with the cables (352) through conduits, cable pathways, etc., and minimize the likelihood of the cable system (350) getting caught or stuck.

Turning the FIG. 4, the bundle clip (400) secures the cables (452). the bundle clip (400) includes the cylindrical channels (470) for the cables (452). Each of the cylindrical channels (470) includes a wall (e.g., the wall (480)) with multiple curves (e.g., the curves (482) and (484)).

Turning to FIG. 5, a side view of the bundle clip (500) is shown. The bundle clip (500) includes the cylindrical channels (502), (505), (508), and (510) for four cables (not shown). The cylindrical channel (502) is formed with the walls (512) and (515). The cylindrical channel (505) is formed with the walls (518) and (520). The cylindrical channel (508) is formed with the walls (522) and (525). The cylindrical channel (510) is formed with the walls (528) and (530). The walls (512) through (530) form flexible channel supports for the cylindrical channels (502) through (510) to allow cables (not shown) to be pushed into the cylindrical channels (502) through (510). In an embodiment, the bundle clip (500) is a UL94 V-O flame rated plastic component.

Each of the walls (512) through (530) has a thickness. The thickness of the walls (512) through (530) is thin enough to flex but thick enough to properly secure the cable. For example, for a cable with a diameter of 5.4 mm (0.21 inches), the thickness may be in the range of 0.75 mm (0.0295 inches) to 1.0 mm (0.0393 inches).

The entrance spacing (532) between the tips of the walls (512) and (515) of the cylindrical channel (502) is less than the diameter of a cable to be fit into the bundle clip (500). The entrance spacing (532) being less than the cable diameter locks the cable into place in the cylindrical channel (502) to prevent the cable from falling out. The tips of the walls (512) through (530) are rounded to reduce damage to cables when inserting into the bundle clip (500).

The void (535) is at a center of the bundle clip (500). The void (535) prevents sink in the finished plastic component.

The bundle clip (500) may support four cables (not shown). A similar design may be used for three cables. When five cables are used, the fifth cable may be placed into a channel inside of the bundle clip (500) where the void (535) is located.

The diameter (538) is a diameter of the cylindrical channel (510), which may be the same as the diameters for the cylindrical channels (502) through (508). The cylindrical channel (510) is less than or equal to a cable diameter of a cable (not shown) to prevent sliding of the cable after installation into the bundle clip (500).

Turning to FIG. 6, a longitudinal view of the bundle clip (600) is shown. The bundle clip (600) includes the wall (602).

The wall (602) includes the double curvature shape (605) that allows a cable (not shown) to be easily inserted into the bundle clip (600). The double curvature shape (605) also prevents the bundle clip (600) from getting snagged on other component edges, cables, cable trays and pathways, equipment, etc. The double curvature shape (605) includes the convex curvature (608) and the concave curvature (610). The double curvature shape (605) forms an edge of the wall (602) that between the exterior surface (612) and an interior surface (occluded) of the wall (602).

The profiled edge (615) may be rounded to allow the bundle clip (600) to be routed through a pathway without snagging. In different embodiments, the profiled edge (615) may be beveled, chamfered, filleted, curved, etc.

The parting line (620) may be in the middle of the bundle clip (600) to control the dimensions of the bundle clip (600) more accurately during manufacturing. In a different embodiment, the parting line (620) may be offset to one side to allow the cable to be inserted more easily from one end.

The length of the bundle clip (600) is long enough to properly secure cables within the bundle clip (600) but short enough to allow the cables to flex and bend around obstacles without getting snagged. For example, the length of the bundle clip (600) may be in the range of 0.75 inches (19 mm) to 1.5 inches (38 mm).

Turning to FIG. 7, a perspective view of the bundle clip (700) is shown. The profiled edge (702) extends around the side face (705) of the bundle clip (700). The profiled edge (702) is between the side face (705) of the bundle clip (700) and the interior surfaces (708), (710), (712), and (715) and between the side face (705) and the exterior surfaces (718), (720), and (722).

The pair of extensions (725) and (728) extend from the center of the bundle clip (700). Each of the extensions (725) and (728) form a pair of the cylindrical channels to support a pair of cables (not shown). For example, the extension (725) forms part of the cylindrical channels formed by the interior surfaces (708) and (710), and the extension (728) forms part of the cylindrical channels formed by the interior surfaces (710) and (712).

The walls (730) and (732) include the rounded tips (735) and (738). The rounded tips (735) and (738) prevent damage to a cable when inserted into the cylindrical channel (710).

Turning to FIG. 8, a perspective view of the panel (800) is shown. The panel (800) includes the modules (802). The modules (802) may be used to terminate one or more cables that are secured with bundle clips. The panel (800) may be fitted to a rack of a cabinet in a data center. The modules (802) terminating a set of cables may be pulled through various conduits, tight spaces, and corners without snagging to the use of the bundle clips.

The term “about,” when used with respect to a physical property that may be measured, refers to an engineering tolerance expected by or determined by one ordinary skill in the art. The exact quantified degree of an engineering tolerance depends on the product being produced, the process being performed, or the technical property being measured. For a non-limiting example, two angles may be “about congruent” if the values of the two angles are within ten percent of each other. However, if the ordinary artisan determines that the engineering tolerance for a particular product should be tighter, then “about congruent” could be two angles having values that are within one percent of each other. Likewise, engineering tolerances could be loosened in other embodiments, such that “about congruent” angles have values within twenty percent of each other. In any case, the ordinary artisan is capable of assessing what is an acceptable engineering tolerance for a particular product, and thus is capable of assessing how to determine the variance of measurement contemplated by the term “about.”

As used herein, the term “connected to” contemplates at least two meanings. In a first meaning, unless otherwise stated, “connected to” means that component A could have been separate from component B but is joined to component B in either a fixed or a removably attached arrangement. In a second meaning, unless otherwise stated, “connected to” means that component A is integrally formed with component B. Thus, for example, assume a bottom of a pan is “connected to” a wall of the pan. The term “connected to” may be interpreted as the bottom and the wall being separate components that are snapped together, welded, or are otherwise fixedly or removably attached to each other. Additionally, the term “connected to” also may be interpreted as the bottom and the wall being contiguously together as a monocoque body formed by, for example, a molding process.

The various descriptions of the figures may be combined and may include or be included within the features described in the other figures of the application. The various elements, systems, components, and steps shown in the figures may be omitted, repeated, combined, and/or altered as shown from the figures. Accordingly, the scope of the present disclosure should not be considered limited to the specific arrangements shown in the figures.

In the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Further, unless expressly stated otherwise, the term “or” is an “inclusive or” and, as such, includes the term “and.” Further, items joined by the term “or” may include any combination of the items with any number of each item, unless expressly stated otherwise.

In the above description, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description. Further, other embodiments not explicitly described above can be devised which do not depart from the scope of the invention as disclosed herein. Accordingly, the scope of the invention should be limited only by the attached claims.

What is claimed is:

1. An apparatus comprising:
a plurality of cylindrical channels of a bundle clip to secure a plurality of cables;
a wall of a cylindrical channel, of the plurality of cylindrical channels, comprising a plurality of curves; and
an edge of the wall between an interior surface and an exterior surface comprising a convex curvature and a concave curvature, wherein the convex curvature is proximal to a center of the bundle clip and the concave curvature distal to the center of the bundle clip.

2. The apparatus of claim 1, further comprising:
the interior surface of the wall extending to a second wall.

3. The apparatus of claim 1, further comprising:
the exterior surface of the wall extending to a third wall.

4. The apparatus of claim 1, further comprising:
a profiled edge between a side face of the bundle clip and a plurality of interior surfaces, including the interior surface, and between the side face and a plurality of exterior surfaces, including the exterior surface.

5. The apparatus of claim 1, further comprising:
a pair of extensions extending from a center of the bundle clip, each extension of the pair of extensions forming a pair of the cylindrical channels of the plurality of cylindrical channels to support a pair of cables of the plurality of cables.

6. The apparatus of claim 1, further comprising:
the plurality of cables comprising at least three cables and filling the plurality of cylindrical channels.

7. The apparatus of claim 1, further comprising:
a void at the center of the bundle clip.

8. The apparatus of claim 1, further comprising:
an opening of the cylindrical channel forming an entrance spacing that is less than a diameter of a cable, of the plurality of cables, insert into the cylindrical channel.

9. The apparatus of claim 1, further comprising:
the wall forming a flexible channel support.

10. The apparatus of claim 1, further comprising:
a rounded tip of the wall to prevent damaging the plurality of cables.

11. A system, comprising:
a plurality of bundle clips comprising a bundle clip, wherein the bundle clip comprises:
a plurality of cylindrical channels of the bundle clip to secure a plurality of cables;
a wall of a cylindrical channel, of the plurality of cylindrical channels, comprising a plurality of curves; and
an edge of the wall between an interior surface and an exterior surface comprising a convex curvature and a concave curvature, wherein the convex curvature is proximal to a center of the bundle clip and the concave curvature distal to the center of the bundle clip;
a plurality of cables disposed within the plurality of channels; and
at least one module connected to the plurality of cables and comprising a plurality of adapters corresponding to the plurality of cables and to the plurality of channels of the bundle clip.

12. The system of claim 11, further comprising:
a panel comprising the module;
a rack comprising the panel; and
a cabinet comprising the rack.

13. The system of claim 11, wherein the bundle clip further comprises:
the interior surface of the wall extending to a second wall.

14. The system of claim 11, wherein the bundle clip further comprises:
the exterior surface of the wall extending to a third wall.

15. The system of claim 11, wherein the bundle clip further comprises:
a profiled edge between a side face of the bundle clip and a plurality of interior surfaces, including the interior surface, and between the side face and a plurality of exterior surfaces, including the exterior surface.

16. The system of claim 11, wherein the bundle clip further comprises:
a pair of extensions extending from a center of the bundle clip, each extension of the pair of extensions forming a pair of the cylindrical channels of the plurality of cylindrical channels to support a pair of cables of the plurality of cables.

17. The system of claim 11, wherein the bundle clip further comprises:
the plurality of cables comprising at least three cables and filling the plurality of cylindrical channels.

18. The system of claim 11, wherein the bundle clip further comprises:
a void at the center of the bundle clip.

19. The system of claim 11, wherein the bundle clip further comprises:
an opening of the cylindrical channel forming an entrance spacing that is less than a diameter of a cable, of the plurality of cables, insert into the cylindrical channel.

20. A method comprising:
inserting a plurality of cables into a plurality of channels of one or more bundle clips, wherein a bundle clip of the one or more bundle clips comprises:
a plurality of cylindrical channels of a bundle clip to secure a plurality of cables;
a wall of a cylindrical channel, of the plurality of cylindrical channels, comprising a plurality of curves; and
an edge of the wall between an interior surface and an exterior surface comprising a convex curvature and a concave curvature, wherein the convex curvature is proximal to a center of the bundle clip and the concave curvature distal to the center of the bundle clip; and
installing the plurality of cables to a set of telecommunications equipment.
